(19) United States
(12) Patent Application Publication
(10) Pub. No.: US 2011/0025619 A1
(43) Pub. Date: Feb. 3, 2011

(54) ELECTRONIC ANALYSIS CIRCUIT WITH MODULATION OF SCANNING CHARACTERISTICS FOR PASSIVE-MATRIX MULTICONTACT TACTILE SENSOR

(75) Inventors: Pascal Joguet, Sadirac (FR); Guillaume Largillier, Bordeaux (FR); Julien Olivier, Bordeaux (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: STANTUM, BORDEAUX (FR)

(21) Appl. No.: 12/809,349

(22) PCT Filed: Dec. 19, 2008
(86) PCT No.: PCT/FR2008/001809

§ 371 Date: Oct. 20, 2010

(30) Foreign Application Priority Data
Dec. 19, 2007 (FR) 0760021

(51) Int. Cl. G06F 3/041; G01R 27/08

(52) U.S. Cl. 345/173; 324/707

(57) ABSTRACT

An electronic analysis circuit for a multicontact passive-matrix tactile sensor including an electrical supply mechanism powering one of two axes of the matrix, and a mechanism detecting electrical characteristics along the other axis of the matrix, at nodes between the two axes. At least one scanning characteristic is modulated locally or temporally. A multicontact passive-matrix tactile sensor can include such an electronic analysis circuit.

The present invention concerns an electronic analysis circuit with modulation of scanning characteristics for passive-matrix multicontact tactile sensors.

The present invention concerns the field of transparent multicontact tactile sensors.

This type of sensor is provided with means for simultaneous acquisition of the position, the pressure, the size, the shape and the movement of a number of fingers on its surface, in order to control a device, preferably via a graphical interface.

Said sensors may be used as interfaces for personal computers, portable or otherwise, cellular telephones, automatic teller machines (banks, points of sale, ticket sales), games consoles, portable multimedia players (digital walkman), control of audiovisual equipment or domestic electrical appliances, control of industrial equipment, GPS navigation devices (the above list is not limiting on the invention).

There are known in the art transparent multicontact tactile sensors enabling detection of the presence and the status of a plurality of points of contact at the same time. Such a sensor can be of matrix type. To this end the voltage at the terminals of each node of the matrix is measured sequentially and quickly in order to recreate an image of the sensor several times per second.

With a view to use of these sensors in applications necessitating an imperceptible reaction time (typing, video games, musical or multimedia application control), it is imperative to be able to measure the activity of a finger with a maximum latency of 20 milliseconds.

One solution that has been proposed in the prior art is described in the patent FR 2,866,726 and is aimed at a control device for manipulating virtual graphic objects on a multicontact tactile screen. Said device further comprises an analysis electronic circuit making it possible to acquire and analyze data from the sensor using a sampling frequency of 100 Hz. The sensor can be divided into a plurality of areas in order to effect parallel processing of said areas.

The drawback of this solution resides in the measurement accuracy of the analysis electronic circuit. This accuracy is directly dependent on the sampling frequency, and consequently is the same all over the sensor, independently of contact with any given area thereof. Similarly, each scanning phase necessitates a high scanning resolution.

In order to obtain sufficiently accurate measurements, it is therefore necessary to use unnecessary scanning at an unnecessarily high frequency and an unnecessarily high resolution over the whole of the sensor. This leads to high consumption of electrical energy by the tactile screen into which the electronic analysis circuit is integrated.

The object of the present invention is to remedy this drawback by proposing an electronic controller for a passive-matrix multicontact tactile sensor that is adapted to modulate the scanning characteristics in some acquisition phases.

This modulation may consist in adaptation of the scanning frequency so as to enable at the same time low-frequency scanning over the whole of the matrix sensor and high-frequency scanning over one or more areas of the sensor through conditional and localized control of scanning.

This modulation can also consist in adaptation of the scanning resolution of the matrix sensor, i.e. using a low resolution over the whole of the sensor and a high resolution over one or more specific areas of the sensor.

The invention can also consist in a combination of the two modulation modes.

To this end, the present invention proposes an analyzer electronic circuit for passive-matrix multicontact tactile sensor including means for energization of one of the two axes of the matrix and means for detecting electrical characteristics on the other axis of the matrix at the nodes between the two axes, characterized in that at least one scanning characteristic is modulated locally or temporally.

In a first embodiment said modulation consists in modifying the scanning frequency locally or temporally.

In a second embodiment said modulation consists in modifying the scanning resolution locally or temporally.

In a third embodiment said modulation consists in modifying the scanning resolution and frequency locally or temporally.

Scanning is advantageously effected using a set of low scanning characteristics over the whole of the surface of the sensor and using at least one set of high scanning characteristics over at least one smaller area.

According to other particular embodiments of the invention:
at least one small area is a contact area in which contact has been detected during scanning using a set of low scanning characteristics;
scanning using at least one set of high scanning characteristics is conditioned by the detection, if any, of a contact area during scanning using a set of low scanning characteristics;
the limits of the area scanned using at least one set of high scanning characteristics are determined as a function of the contour of the contact area detected during scanning using a set of low scanning characteristics;
the limits of the area scanned using at least one set of high scanning characteristics are updated after each scan using a set of low scanning characteristics;
at least one set of high scanning characteristics is a function of the size of the area to be scanned.

The invention thus offers faster and more reliable analysis with optimized electrical power consumption.

According to other particular embodiments of the invention:
at least one small area is an area corresponding to the location of a graphic object;
a small area corresponding to the location of a graphic object is scanned using a set of high scanning characteristics which is a function of the characteristics of said graphic object;
the analysis of the area scanned using at least one set of high scanning characteristics further includes filtering steps more sophisticated than those used during the analysis of the whole of the surface of the sensor using a set of low scanning characteristics.

The invention thus makes it possible to improve the linking of the scanning with the shape of the associated graphic objects.

According to one particular embodiment of the invention, the modulation is a function of the graphic elements displayed on the tactile screen.

According to one particular embodiment of the invention, the modulation is a function of the result of the detection, if any, of a contact point.

According to one particular embodiment of the invention, there is no scanning of parts of the tactile screen not including a graphic object. This avoids unnecessary acquisition in areas for which the contact information is not necessary.

According to one particular embodiment of the invention, the analyzer electronic circuit controls the sensor during a scanning phase by energizing the successive tracks of one of the networks and detecting the response on each of the tracks of the second network.

The invention also concerns a passive-matrix multicontact tactile sensor including means for energization of one of the two axes of the matrix and means for detecting electrical characteristics on the other axis of the matrix at the nodes between the two axes, said sensor also including an analyzer electronic circuit according to any of the preceding claims.

This patent refers to a high scanning characteristic when the latter scanning produces a high scanning quality. It refers to a low characteristic when the latter scanning produces a low scanning quality. In particular, a high resolution and a high scanning frequency correspond to high scanning characteristics. A low resolution and a low scanning frequency correspond to low scanning characteristics.

The invention will be better understood after reading the detailed description of one non-limiting embodiment of the invention accompanied by appended figures respectively representing:

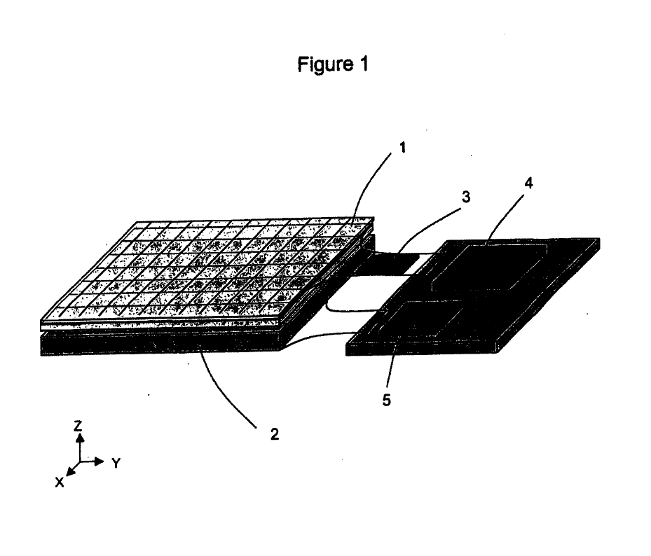

FIG. 1, a view of a passive-matrix multicontact tactile electronic device,

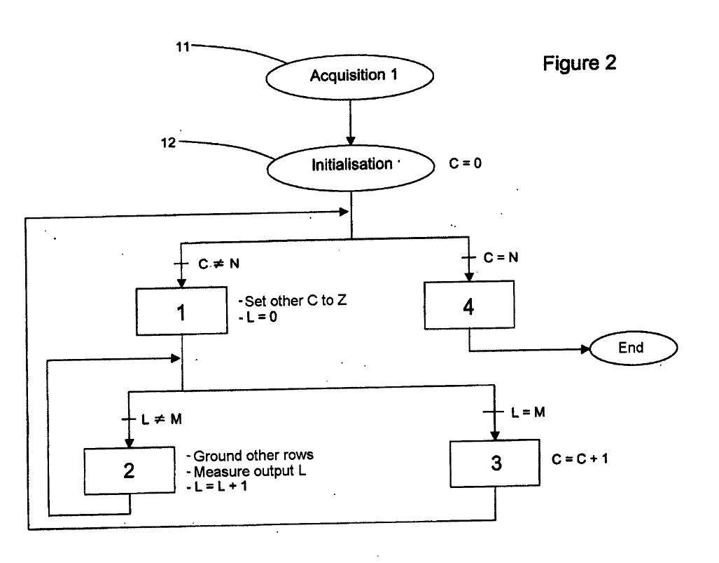

FIG. 2, a diagram of a prior art method “acquisition 1” of acquisition of data by the electronic circuit over the whole of the sensor,

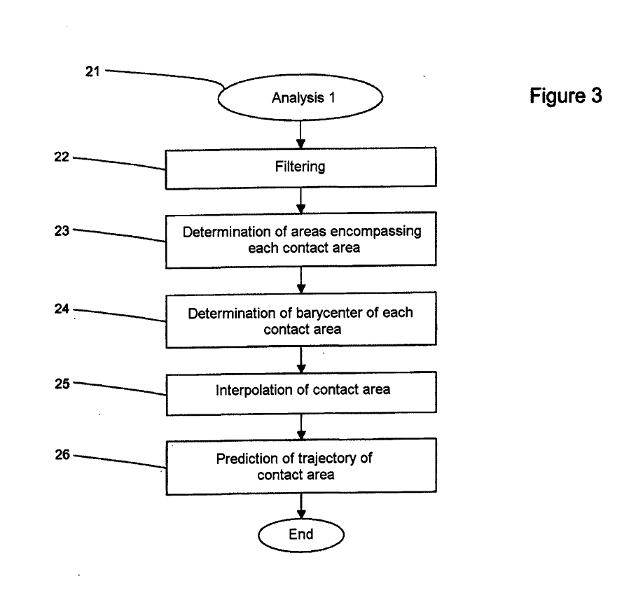

FIG. 3, a diagram of a data analysis method “analysis 1” used by the prior art electronic circuit,

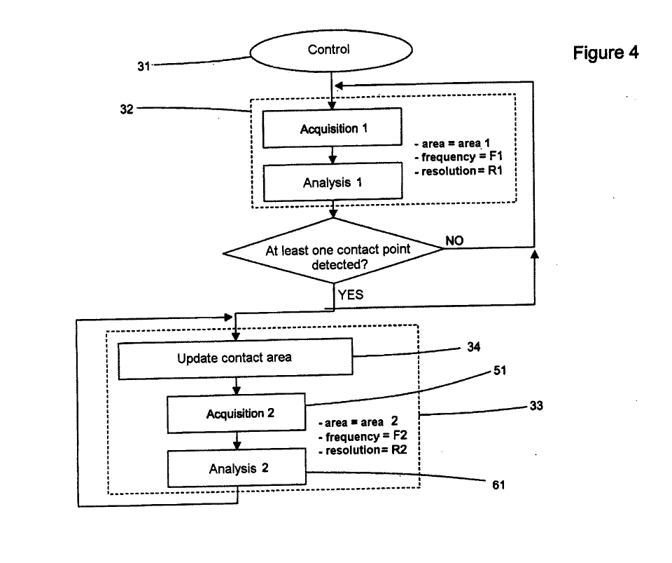

FIG. 4, a diagram of a conditional and localized method “control 1” of controlling the scanning of the sensor used by the electronic circuit of the present invention,

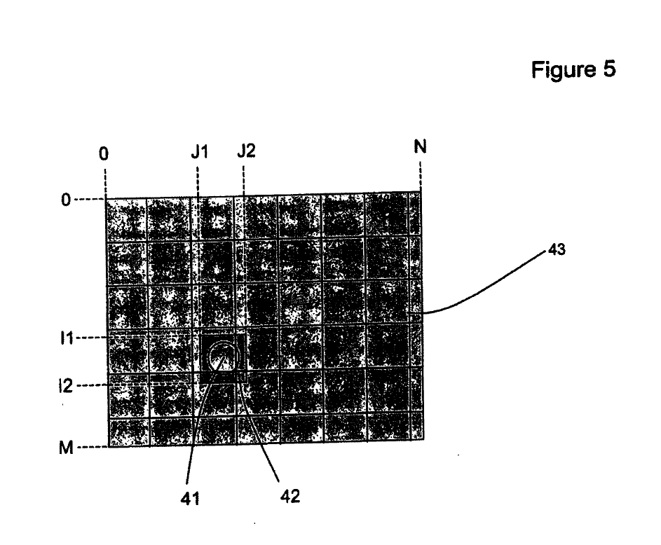

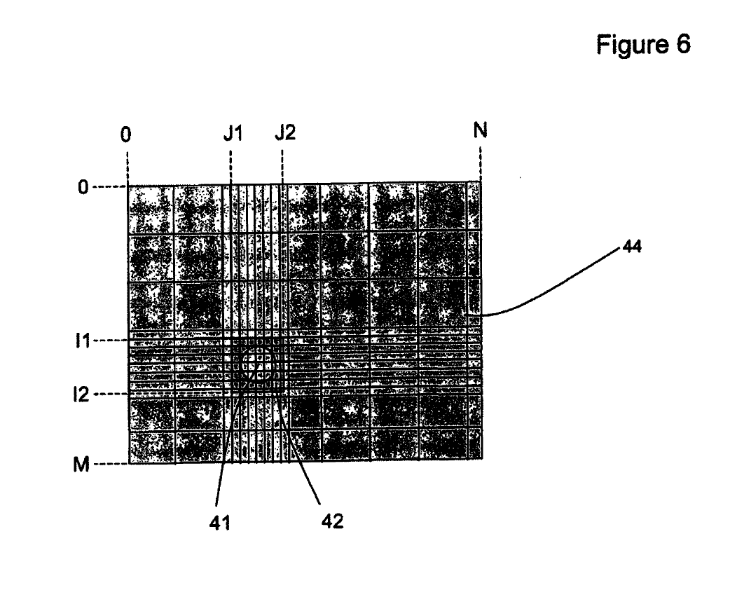

FIGS. 5 and 6, views of a matrix sensor on which one contact is made,

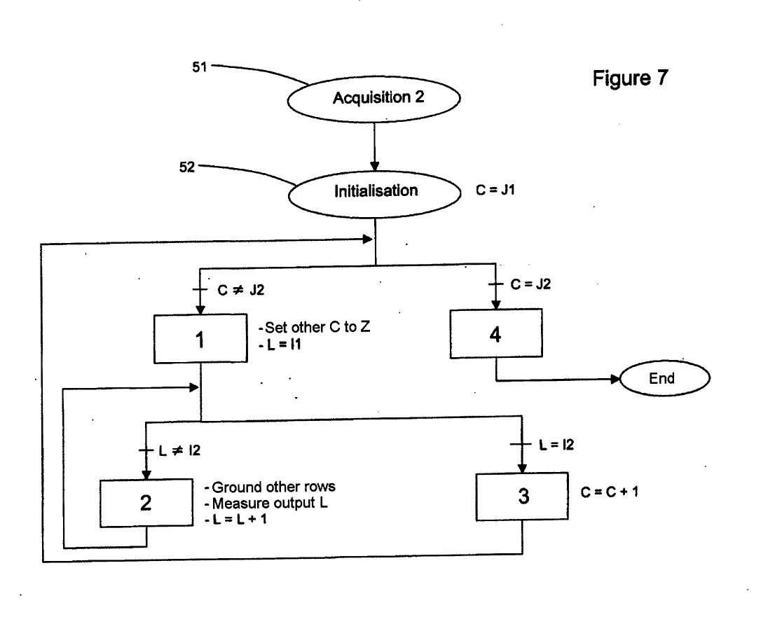

FIG. 7, a diagram of the data acquisition method “acquisition 2” used by the electronic circuit of the present invention,

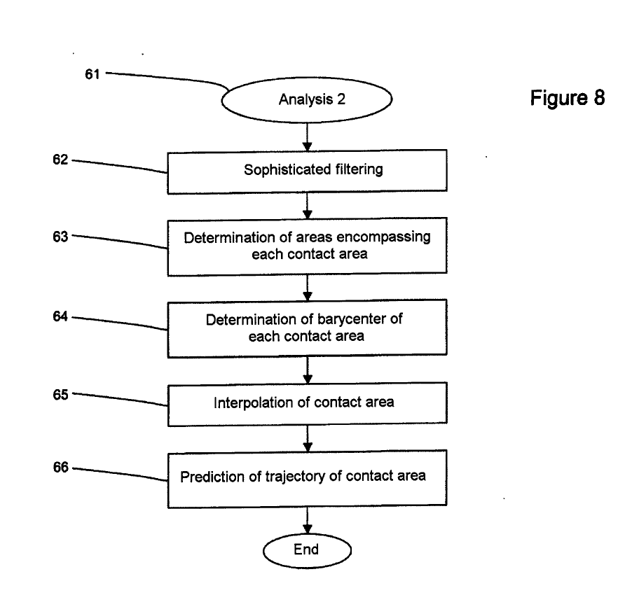

FIG. 8, a diagram of the data analysis method “analysis 2” used by the electronic circuit of the present invention,

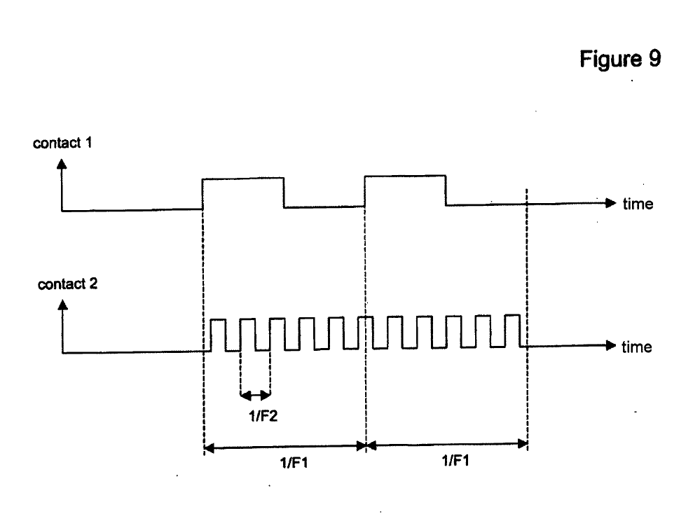

FIG. 9, a timing diagram of two loops employed by the conditional and localized control method,

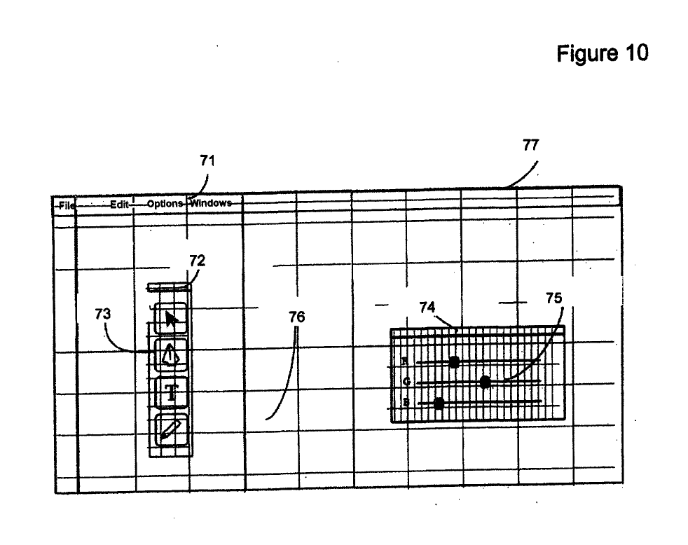

FIG. 10, a known type of graphical user interface used in the present invention,

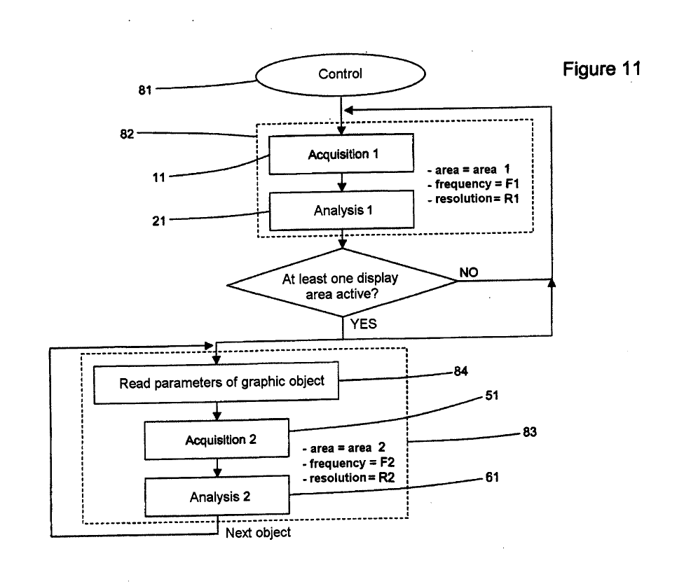

FIG. 11, a diagram of the method “control 2” of analyzing data as a function of different display areas employed by the electronic circuit of the present invention, and

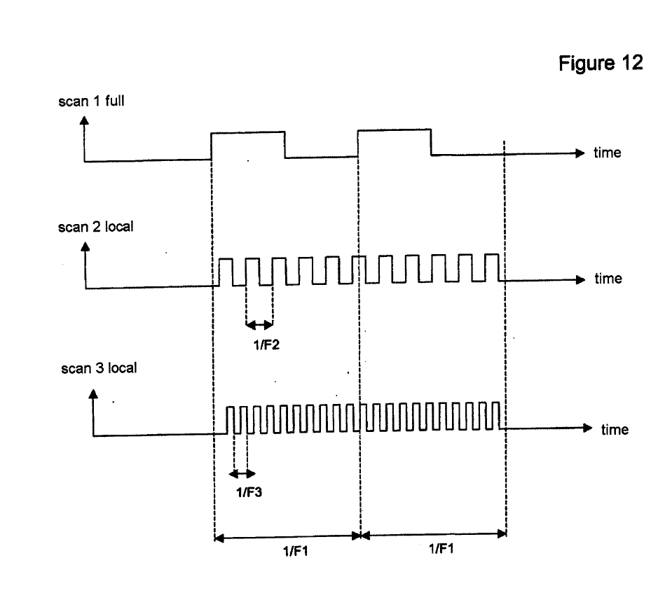

FIG. 12, a timing diagram of loops employed by the localized control method and conditional on the definition of the various tactile areas.

An electronic analysis circuit of the invention is intended to be integrated into a matrix type multicontact tactile sensor. The matrix can be a passive matrix, i.e. one made up of two layers of transparent conductive material arranged as a matrix and separated by an insulative layer, or an active matrix, in which each node of the matrix consists of an active component such as a transistor or a diode.

FIG. 1 represents a view of a tactile electronic device comprising:
a matrix tactile sensor 1,
a display screen 2,
a capture interface 3,
a main processor 4, and
a graphic processor 5.

The first fundamental element of said tactile device is the tactile sensor 1, necessary for multicontact acquisition and manipulation with the aid of a capture interface 3. This capture interface 3 includes acquisition and analysis circuits.

Said tactile sensor 1 is of matrix type. Said sensor may be divided into a plurality of portions in order to accelerate capture, each portion being scanned simultaneously.

Data from the capture interface 3 is transmitted after filtering to the main processor 4. The latter executes the local program making it possible to associate data from the pad with graphic objects that are displayed on the screen 2 in order to be manipulated.

The main processor 4 also sends the graphical user interface the data to be displayed on the display screen 2. This graphical user interface can be driven by a graphics processor 5.

The tactile sensor is controlled in the following manner: during a first scanning phase, the tracks of one of the networks are energized successively and the response on each of the tracks of the second network is detected. Contact areas are determined as a function of these responses that correspond to the nodes the state whereof is modified relative to the idle state. One or more sets of adjacent nodes the state whereof is modified are determined. A set of such adjacent nodes defines a contact area. Position information referred to in the present patent as a cursor is calculated from this set of nodes. In the case of a plurality of sets of nodes separated by non-active areas, a plurality of independent cursors is determined during the same scanning phase.

This information is refreshed periodically during new scanning phases.

The cursors are created, tracked or destroyed as a function of information obtained during successive scans. For example, the cursor is calculated by a contact area barycenter function.

The general principle is to create as many cursors as there are areas detected on the tactile sensor and to follow their evolution in time. When the user removes his fingers from the sensor, the associated cursors are destroyed. In this way it is possible to capture simultaneously the position and the movement of a plurality of fingers on the tactile sensor.

The matrix sensor 1 is a resistive type sensor or a projected capacitive type sensor, for example. It consists of two transparent layers on which conductive wires are set out in rows and columns. Said layers thus form a matrix network of conductive wires.

To find out if a row has been brought into contact with a column, determining a point of contact on the sensor 1, the electrical characteristics—voltage, capacitance or inductance—at the terminals of each node of the matrix are measured.

The device makes it possible to acquire data over the whole of the sensor 1 with a sampling frequency of the order of 100 Hz using the sensor 1 and the control circuit integrated into the main processor 4.

The main processor 4 executes a program making it possible to associate data from the sensor with graphic objects that are displayed on the display screen 2 in order to be manipulated.

FIG. 2 represents a diagram of the “acquisition 1” method 11 of acquisition of data over the area Z1 used by a prior art electronic circuit.

The function of this method is to determine the state of each point of the area Z1 of the matrix sensor 1, namely whether said point makes contact or not. Said area Z1 of the sensor comprises M rows and N columns and corresponds to the whole of the sensor.

The sampling frequency for the rows and columns of the area is 100 Hz.

Said method corresponds to measuring all the nodes over the area of the matrix. The electrical characteristic measured at each node of the matrix is the voltage, for example. Said matrix is an [N,M] matrix containing at each point (I,J) the value of the voltage measured at the terminals of a node formed by the intersection of the row I and the column J, with 1≦I≦N and 1≦J≦M. This method makes it possible to give the state of each node of the matrix sensor 1 at a given time.

The “acquisition 1” method 11 begins with a step 12 of initializing data obtained during a preceding acquisition.

Here the column axis constitutes the energization axis and the row axis constitutes the detection axis.

The method 11 first scans the first column. It is energized at 5 volts, for example. The electronic circuit measures the electrical characteristic, for example the voltage, at the terminals of the node between said column and each of rows 1 to N.

When the measurement has been effected for the Nth row, the method proceeds to the next column and starts to measure the voltage at the terminals of each node of the new column and each of rows 1 to N.

When all the columns have been scanned, the voltages at the terminals of each of the points of the matrix sensor 1 have been measured. This terminates the method and the electronic circuit can proceed to analyze the “voltage” matrix obtained.

FIG. 3 represents a diagram of the “analysis 1” method 21 of analyzing data used by the prior art electronic circuit.

Said method consists of a series of algorithms performing the following steps:
one or more filter steps 22,
determination 23 of the areas encompassing each contact area,
determination 24 of the barycenter of each contact area,
interpolation 25 of the contact area, and
prediction 26 of the trajectory of the contact area.

Once the “analysis 1” method 21 has finished, the software is able to apply specific processing operations to the virtual graphic objects on the tactile screen in order to refresh said tactile screen in real time. Areas encompassing the contact areas detected during the data acquisition step 11 are also defined.

The prior art electronic circuit repeats the methods 11 and 21 in a loop at a frequency of the order of 100 Hz. The drawback of such an electronic circuit is the difficulty of arbitrating between a calculation overload, causing excessive electrical power consumption, and the resolution of the measured states at the contact points, making the tactile screen unreliable and insensitive.

To alleviate the drawbacks of the prior art, the electronic circuit integrates a method for conditional and localized control of the scanning of the sensor and adopts two scanning modes:
a first scanning mode at a low frequency F1 and a low resolution R1 over an area Z1 of the sensor, possibly the whole of the surface of the matrix sensor, for example, and
a second scanning mode at a high frequency F2 and a resolution R2 equal to or greater than F1 and R1, respectively, over only the contact areas Z2 included within the contact area Z1 delimited during the overall analysis following on from the scanning of area Z1 in the first scanning mode.

For example, the low scanning frequency F1 is 20 hertz or less, for example 1 hertz. For example, the high scanning frequency F2 is 100 hertz or more, for example 200 hertz.

The frequency and the resolution are defined as scanning characteristics.

FIG. 4 represents a diagram of the “control 1” method of conditional and localized control of the scanning of the sensor 31 by the electronic circuit of the present invention.

This method comprises a first loop 32 corresponding to the succession of steps 11 and 21, i.e. the steps of acquisition and analysis of data from the area Z1 of the matrix sensor (9).

This first loop (32) is executed over the whole of the area Z1 of the matrix sensor at a low frequency F1 and at a low resolution R1.

The frequency F1 is equal to 20 hertz, for example. The low resolution R1 for its part is an integer fraction of the resolution of the matrix sensor. For example, during this first loop, one row in two is energized and one column in two is measured. In this case, R1 is equal to M×N/4.

At the end of said first loop 32, conditional and localized control is applied. If at least one contact point is detected over the whole of the area Z1, the method enters the second loop 33 corresponding to the succession of steps 34, 51 and 61.

Said second loop 33 comprises a first step 34 of updating the area 42 encompassing the contact area 41, as shown in FIG. 5. Said area 42 is obtained after analysis of the data over the whole of the area Z1 during the analysis step 21 of the first loop 32.

The second loop 33 is effected at a frequency F2. This frequency is greater than F1. For example, it may be equal to 100 Hz. The second loop 33 is effected at a resolution R2 different from R1. For example, R2 can be equal to the resolution of the matrix sensor. In this case, R2 is equal to M×N. When there is no longer any contact detected in the area Z2, the loop 33 stops.

Throughout the execution of said second loop 33, said first loop 32 continues to be operative. Each time said first loop 32 ends, conditional and localized control is again applied. If a new contact point is detected the second loop 33 is restarted.

The output data from the analysis step 21 gives the state of each of the points of the sensor 1, notably in order to locate one or more contacts.

As shown in FIG. 6, when an object comes into contact with the matrix sensor 1, a contact area 41 is detected on the sensor after the acquisition step 11. Said area 41 is then processed during the analysis step in order to determine an area 42 encompassing said contact area 41. The shape of said area 42 is a parameter of the electronic circuit. In a first embodiment of the invention, it may be a rectangular shape. However, the invention can be implemented with any other shape of the area.

If the electronic circuit detects a plurality of distinct contact areas 41 over the whole of the matrix sensor 1, a plurality of encompassing areas 42 is defined.

The encompassing area 42 defines the coordinates and the perimeter of the area Z2 to be analyzed in the second scanning mode, as shown in FIG. 6.

FIGS. 5 and 6 also show the difference between the resolutions of the two scanning modes. The resolution R2 for scanning the area Z2 is five times the resolution R1 for scanning the area Z1. Scanning the area Z1 as shown in FIG. 5 is thus effected with one fifth the resolution of scanning the area Z2 as shown in FIG. 6.

The subdivision 43 of the area Z1 shown in FIG. 5 is five times greater than the subdivision 44 of the area Z2 shown in FIG. 6.

FIG. 7 represents a diagram of the “acquisition 2” method 51 of data acquisition used by the electronic circuit of the present invention.

Here, the method 51 is analogous to the “acquisition 1” data acquisition method 11 used by the electronic circuit at the frequency F1 over the whole of the area Z1.

It is nevertheless different in that acquisition is effected over only the areas encompassing the calculated contact areas, i.e. the areas Z2.

In the case of a single detected area 41, the encompassing area 42 of which is of rectangular shape, the contour is defined by the integer parameters I1, I2, J1, J2. The method 51 scans the rows I1 to I2 in each column from J1 to J2 so as to measure the voltage at the terminals of each point of the rectangle [I1,I2,J1,J2].

This example is for an area 42 of rectangular shape. That shape is obviously not limiting on the invention, it being understood that it is obvious to the person skilled in the art how to perform the method 51 for an area 42 that is not necessarily rectangular, but of any other shape.

FIG. 8 represents a diagram of the “analysis 2” data analysis method 61 used by the electronic circuit of the present invention.

The area Z2 over which the analysis step 61 is effected corresponds to the area 42 encompassing the area 41 described above. Because the area Z2 is much smaller than the area Z1, the analysis method 61 preferably uses more sophisticated filtering during the filtering step 62 than is used during the filtering step 22.

By way of illustration, FIG. 9 represents a timing diagram of the two loops 32 and 33 performed during conditional and localized control 31 in a precise situation in which a contact is detected during the first two periods and no contact is detected during the third period.

The conditional and localized control 31 makes it possible to trigger the second loop 33 at the frequency F2 and the resolution R2 as a function of the result of detection, if any, of a contact point on exit from the first loop 32. Said second loop 33 is then effected at the frequency F2.

According to the present invention, the frequency F2 is higher than the frequency F1.

The “contact 1” function is defined as a function liable to take two values: a high value if at least one contact is detected over the whole of the area of the sensor 1 on exit from the first loop 32, and a low value otherwise. Said “contact 1” function is updated at the end of the first loop 32 at the frequency F1.

As soon as the “contact 1” function goes to its high value, the second loop 33 is effected at the frequency F2. Said second loop 33 additionally generates a “contact 2” function analogous to said “contact 1” function, but over only the area 42 obtained on exit from the first loop 32 and updated in the step 34.

In the present example, the “contact 1” function takes its high value during the first two periods. The “contact 2” function then likewise goes to its high value.

During the third period, no further contact is detected over the whole of the matrix sensor and the “contact 1” function therefore goes to its low value, as a consequence of which the second loop 33 is stopped.

Another embodiment of the present invention modulates the scanning resolution locally, as a function of the graphics elements displayed on the tactile screen. This reduced scanning resolution can be limited to one or more areas in which the probability of contact is low, or even where it is wished to inhibit the tactile functions.

Accordingly, FIG. 10 shows a graphical user interface (GUI) 77 of known type. It consists of a set of graphical objects, which graphical objects can be included in subsets of the graphical user interface 77. Said subsets of the graphical user interface 77 are commonly called “windows”.

The windows 71 and 74 are thus subsets of the interface 77. The objects 73 are included in the window and the objects 75 are part of the window 74. The interface 77 also contains a neutral tactile area 76, i.e. one containing no graphic object liable to be manipulated by the user.

The objects contained in the windows 71 and 74 are of different types. The objects 73 are buttons activated by contact. They can be used, for example, to select a tool or a function. The objects 75 are sliders manipulated by stroking with the finger to modify software or hardware parameters, for example.

These objects of different types do not require the same tactile accuracy. Buttons do not require a high resolution but to make fine adjustments sliders require the highest possible resolution. Conversely, activation of a button requires a good response time but movement of a slider is less sensitive to this parameter.

The neutral area 76 for its part requires neither a high resolution nor a high frequency. It can optionally not be scanned.

The meshing in FIG. 10 shows the levels of resolution required for the subsets of the graphical user interface 77.

In this embodiment of the invention, acquisition of tactile data is enhanced and optimized by adapting the resolution and the scanning frequency as a function of tactile areas defined as a function of the corresponding graphic objects.

To this end, the control circuit is slaved to the main processor 4 in order for the latter to be able to modify the scanning parameters dynamically as a function of the graphic objects displayed.

In one particular embodiment in which the write function has been activated, the matrix of the multicontact tactile sensor is acquired with a higher resolution in the area where writing is detected by the presence of a contact area. This area of higher resolution encompasses an area larger than the contact area. Thus the resolution is increased in a small area around the last contact point detected, which makes it possible to anticipate the movement of the stylus during the next acquisition. Thus commensurately more accurate tactile information is obtained near the contact area.

In one particular embodiment, a graphic object 73 or 74 is acquired at low frequency and low resolution when there is no contact and, as soon as contact is detected and for as long as contact continues to be detected, the graphic object is acquired at high frequency and high resolution.

In one particular embodiment, for a given graphic object 74 or 75, when contact is detected and for as long as that contact continues to be detected, the resolution is higher over an area close to the area of contact and lower over a more distant area. This makes it possible to have better information on the movement of the contact on fast movement of the cursor.

In one particular embodiment, one energization or detection axis can have a higher resolution (or frequency) than the other axis, which is useful when analyzing cursor movement along one of the two axes predominates.

FIG. 11 shows a diagram of a “control 2” control method 81 used in this embodiment. In a first scanning phase 82 identical to the scanning phase 32 described above, an area Z1 is scanned in its entirety at a frequency F1 and with a resolution R1. This area can, for example, be the whole of the sensor or the whole of the graphical user interface.

At the end of this phase 82, a second loop 83 begins if at least one graphic subset (window or object) is displayed on the screen.

This loop 83 includes firstly a step 84 of reading parameters of the graphic object (position, size, frequency, resolution).

The coordinates of the area Z2 are defined by the coordinates of the graphic object displayed on the screen. The scanning frequency F2 and the scanning resolution R2 are defined as a function of the graphic object type (button, slider, etc.).

For example, for a button type object, the frequency F2 is set to 100 hertz and the resolution R2 is four columns by four rows. Similarly, for a slider type object, the frequency F2 is 60 hertz and the resolution 40 columns by 10 rows.

Hereinafter, the area Z2 is scanned at a frequency F2 and with a resolution R2.

If a plurality of graphic subsets is displayed on the screen, the acquisition step 51 and the analysis step 61 are repeated similarly for each of them in succession until all have been scanned. Once all the areas corresponding to the graphic objects in the area Z1 have been scanned, a new scan of the area Z1 is effected.

FIG. 12 is a timing diagram showing parallel scans corresponding to areas of the display.

The whole of the tactile area Z1 is scanned at a frequency F1. Subsets of the tactile area are scanned in parallel with this at respective frequencies F2 and F3. For example, the scanning labeled “scanning 2” corresponds to an area in which slider type objects are displayed and the scanning labeled “scanning 3” corresponds to an area in which button type objects are displayed.

A tactile screen incorporating an analyzer electronic circuit of any of the embodiments described above has the advantage of not necessitating additional consumption of electrical current and not using an extremely high performance processor, whilst providing a contact detection sensitivity and resolution much higher than those of a prior art tactile screen.

The embodiments of the present invention described above are described by way of example and are in no way limiting on the invention. It must be understood that persons skilled in the art are in a position to produce variants of the invention without departing from the scope of the invention.

1-18. (canceled)

19. An analyzer electronic circuit for passive-matrix multicontact tactile sensor comprising:
means for energization of one of two axes of the matrix; and
means for detecting electrical characteristics on the other axis of the matrix at nodes between the two axes,
wherein at least one scanning characteristic is modulated locally or temporally.

20. An analyzer electronic circuit according to claim 19, wherein the modulation modifies scanning frequency locally or temporally.

21. An analyzer electronic circuit according to claim 19, wherein the modulation modifies scanning resolution locally or temporally.

22. An analyzer electronic circuit according to claim 19, wherein the modulation modifies scanning resolution and frequency locally or temporally.

23. An analyzer electronic circuit according to claim 19, wherein scanning is effected using a set of low scanning characteristics over a whole of a surface of the sensor and using at least one set of high scanning characteristics over at least one smaller area.

24. An analyzer electronic circuit according to claim 23, wherein the at least one smaller area is a contact area in which contact has been detected during scanning using a set of low scanning characteristics.

25. An analyzer electronic circuit according to claim 24, wherein the scanning using at least one set of high scanning characteristics is conditioned by detection, if any, of a contact area during scanning using the set of low scanning characteristics.

26. An analyzer electronic circuit according to claim 24, wherein limits of the area scanned using the at least one set of high scanning characteristics are determined as a function of a contour of the contact area detected during scanning using the set of low scanning characteristics.

27. An analyzer electronic circuit according to claim 24, wherein limits of the area scanned using the at least one set of high scanning characteristics are updated after each scan using the set of low scanning characteristics.

28. An analyzer electronic circuit according to claim 24, wherein the at least one set of high scanning characteristics is a function of a size of the area to be scanned.

29. An analyzer electronic circuit according to claim 23, wherein the at least one smaller area is an area corresponding to a location of a graphic object.

30. An analyzer electronic circuit according to claim 29, wherein a small area corresponding to the location of a graphic object is scanned using the set of high scanning characteristics, which is a function of the characteristics of the graphic object.

31. An analyzer electronic circuit according to claim 19, wherein analysis of the area scanned using the at least one set of high scanning characteristics further includes filtering steps more sophisticated than those used during analysis of a whole of the surface of the sensor using the set of low scanning characteristics.

32. An analyzer electronic circuit according to claim 19, wherein the modulation is a function of graphic elements displayed on a tactile screen.

33. An analyzer electronic circuit according to claim 19, wherein the modulation is a function of a result of detection, if any, of a contact point.

34. An analyzer electronic circuit according to claim 19, wherein there is no scanning of parts of a tactile screen not including a graphic object.

35. An analyzer electronic circuit according to claim 19, controlling the sensor during a scanning phase by energizing successive tracks of one of networks and detecting a response on each of the tracks of a second network.

36. A passive-matrix multicontact tactile sensor comprising:
means for energization of one of two axes of the matrix; and
means for detecting electrical characteristics on the other axis of the matrix at nodes between the two axes;
the sensor including an analyzer electronic circuit according to claim 19.
